(19) United States
(12) Patent Application Publication
(10) Pub. No.: US 2017/0222078 A1
(43) Pub. Date: Aug. 3, 2017

(54) PHOTOVOLTAIC MODULE COMPRISING A POLYMER FRONT FACE

(71) Applicants: COMMISSARIAT A L'ENERGIE ATOMIQUE ET AUX ENERGIES ALTERNATIVES, Paris (FR); ARKEMA FRANCE, Colombes (FR)

(72) Inventors: Manuel HIDALGO, Brignais (FR); Julien GAUME, La Tour Du Pin (FR); Stephane GUILLEREZ, Lepin Le Lac (FR); Lionel SICOT, Chambery (FR)

(73) Assignees: COMMISSARIAT A L'ENERGIE ATOMIQUE ET AUX ENERGIES ALTERNATIVES, Paris (FR); ARKEMA FRANCE, Colombes (FR)

(21) Appl. No.: 15/329,060

(22) PCT Filed: Jul. 27, 2015
(86) PCT No.: PCT/EP2015/067108

§ 371 Date: Jan. 25, 2017

(30) Foreign Application Priority Data
Jul. 28, 2014 (FR) 14 57278

(51) Int. Cl. H01L 31/048; H02S 20/20

(52) U.S. Cl. CPC H01L 31/0481; H01L 31/0488; H02S 20/20

(57) ABSTRACT

A photovoltaic module including a transparent first layer forming a front face, plural photovoltaic cells, and an assembly encapsulating the photovoltaic cells. The first layer includes plural plates independent from each other, each plate located opposite a photovoltaic cell. Rigidity of the encapsulating assembly is defined by a Young's modulus of encapsulation material greater than or equal to 75 MPa at ambient temperature and a thickness of the encapsulating assembly between 0.4 and 1 mm. The first layer includes at least one transparent polymer material of acrylic block copolymers or a composition including at least one acrylic block copolymer having formula (A)ₙB, in which: n is an integer greater than or equal to 1; A is an acrylic or methacrylic homo- or copolymer having a glass transition temperature greater than 50° C.; and B is an acrylic or methacrylic homo- or copolymer having a glass transition temperature less than 20° C.

### TECHNICAL FIELD

This invention relates to the field of photovoltaic modules, comprising a set of photovoltaic cells connected together electrically, and in particular so-called “crystalline” photovoltaic cells, i.e. which have a silicon crystal or silicon polycrystalline base.

The invention can be implemented for many applications, being particularly concerned with applications that require the use of photovoltaic modules that are light, flexible and robust with respect to impacts and high mechanical loads. It can as such in particular be applied for buildings such as residences or industrial premises, for example for the carrying out of the roofs thereof, for the designing of urban furniture, for example for public lighting, road signs or recharging electric cars, or also for the integration thereof in zones where traffic is possible, for pedestrians and/or vehicles, such as road surfaces or roads, bike paths, industrial platforms, squares, pavements, among others.

The invention as such proposes a photovoltaic module provided with a front face made of polymer, a photovoltaic structure assembly comprising such a photovoltaic module, the use of such a photovoltaic module for the application thereof on a rigid support, as well as a method for carrying out such a module or such a photovoltaic structure assembly.

### PRIOR ART

A photovoltaic module is an assembly of photovoltaic cells arranged side-by-side between a transparent first layer forming a front face of the photovoltaic module and a second layer forming a rear face of the photovoltaic module.

The first layer forming the front face of the photovoltaic module is advantageously transparent in order to allow the photovoltaic cells to receive a luminous flux. It is conventionally carried out in a single glass plate, having a thickness of about 3 mm. The second layer forming the rear face of the photovoltaic module can be carried out with a glass, metal or plastic base, among others. It is usually formed by a polymer structure with an electrically insulating polymer base, for example of the polyethylene terephthalate (PET) or polyamide (PA) type, that can be protected by a layer or layers with a fluorinated polymers base, such as polyvinyl fluoride (PVF) or polyvinylidene fluoride (PVDF), and that has a thickness of about 300 μm.

The photovoltaic cells can be connected electrically together in series by front and rear electrical contact elements, called connecting conductors, and formed for example by strips of copper, respectively arranged against the front faces (faces located opposite the front face of the photovoltaic module intended to receive a luminous flux) and rear face (faces located opposite the rear face of the photovoltaic module) of each one of the photovoltaic cells.

Moreover, the photovoltaic cells, located between the first and second layers forming respectively the front and rear faces of the photovoltaic module, are encapsulated. Conventionally, the encapsulant chosen corresponds to a polymer of the elastomer (or rubber) type, and can for example consist in the use of two layers (or films) of poly(ethylene vinyl acetate) (EVA) between which the photovoltaic cells and the connecting conductors of the cells are arranged. Each layer of EVA can have a thickness of at least 0.3 mm and a Young's modulus less than or equal to 30 MPa at ambient temperature.

Again usually, the method of carrying out the photovoltaic module comprises a single step of laminating of the various layers described hereinabove, at a temperature greater than or equal to 140° C., or even 150° C., and for a period of at least 8 minutes, even 15 minutes. After this operation of laminating, the two layers of EVA melted in order to form only a single layer in which the photovoltaic cells are embedded.

However, these productions known in prior art of a photovoltaic module are not entirely satisfactory and have several disadvantages for at least some of their applications.

As such, first of all, the presence of a glass plate in order to form the front face of the photovoltaic module is not compatible with some applications of the photovoltaic module which may require a relative lightness and a facility for forming the module. On the contrary, the designs of prior art that use glass as a front face of the photovoltaic modules imply the obtaining of a high weight of the module and a limited integration capacity.

Solutions have been considered in order to replace the front face made of glass of the photovoltaic modules with plastic materials, while still retaining the conventional architecture and the method of for carrying out photovoltaic modules. As examples, patent application FR 2 955 051 A1 and international applications WO 2012/140585 A1 and WO 2011/028513 A2 describe possibilities of alternatives to glass in order to design the front face of photovoltaic modules, among which the use of polymer sheets, of a thickness less than or equal to 500 μm, such as polyvinylidene fluoride (PVDF), ethylene-tetrafluoroethylene (ETFE), polymethyl methacrylate (PMMA) or polycarbonate (PC).

However, simply substituting glass with a polymer material, in order to obtain a light and flexible photovoltaic module, generally results in increased vulnerability of the module to impacts and to mechanical loads, which is unacceptable for some applications. In addition, in these embodiments of prior art, the front face (devoid of glass) of each photovoltaic module is continuous, i.e. it forms a sheet or a unitary plate that covers the entire module. In this way, the flexibility of each photovoltaic module can be limited and above all insufficient. Moreover, this also poses a problem of accentuation of the differential expansion constraints between the various layers of the structure, that can lead to undesirable deformations or delaminations at the interfaces of the structure, as for example at the encapsulating/outer layer interface.

Certain solutions have been proposed aimed at obtaining a relative discontinuity of the front face of a photovoltaic module in order to obtain a better flexibility of the module and to better manage the differential expansion constraints. As such, for example, patent application US 2014/0000683 A1 describes a method for encapsulating photovoltaic cells individually. The encapsulated cells can then be interconnected in order to obtain a supple photovoltaic module. Moreover, patent application US 2014/0030841 A1 discloses the implementing of a photovoltaic module on a flexible substrate. The photovoltaic module is comprised of “sub-modules” comprised of interconnected photovoltaic cells, with each sub-module being electrically independent from the neighbouring sub-modules.

However, the solutions described hereinabove are not entirely satisfactory in terms of flexibility, resistance to impacts and mechanical loads, performance and cost of photovoltaic modules, in particular for constraining applications that stress them substantially in terms of their mechanical resistance. In particular, the materials used in the carrying out of photovoltaic modules according to prior art are not sufficiently satisfactory to respond to such stresses.

### DESCRIPTION OF THE INVENTION

There is therefore a need to propose an alternative solution for the design of a photovoltaic module in order to respond to at least some of the constraints inherent with applications considered by the use of the photovoltaic module, in particular in order to improve the flexibility, rigidity, lightness, flatness and resistance to impacts and mechanical loads of the photovoltaic module.

The invention has for purpose to overcome at least partially the needs mentioned hereinabove and the disadvantages relating to the products of prior art.

The invention also has for object, according to one of its aspects, a photovoltaic module comprising at least:
a transparent first layer forming the front face of the photovoltaic module intended to receive a luminous flux,
a set of a plurality of photovoltaic cells arranged side-by-side and connected together electrically,
an assembly encapsulating the plurality of photovoltaic cells,
a second layer forming the rear face of the photovoltaic module, the encapsulating assembly and the set of a plurality of photovoltaic cells being located between the first and second layers, characterised in that the first layer consists of at least one transparent polymer material, and comprises a plurality of plates independent from each other, each plate being located opposite at least one photovoltaic cell, in such a way as to form a discontinuous front face of the photovoltaic module, and in that the rigidity of the encapsulating assembly is defined by a Young's modulus of the encapsulation material greater than or equal to 75 MPa at ambient temperature and a thickness of the encapsulating assembly between 0.4 and 1 mm.

Said at least one transparent polymer material comprising the first layer advantageously belongs to the acrylic block polymers or of a composition comprising at least one acrylic block copolymer having the following general formula:

(A)ₙB

wherein:
n is an integer greater than or equal to 1;
A is an acrylic or methacrylic homo- or copolymer having a glass transition temperature Tg greater than 50° C., more preferably greater than 80° C., or polystyrene, or an acrylic-styrene or methacrylic-styrene copolymer; and
B is an acrylic or methacrylic homo- or copolymer having a glass transition temperature Tg less than 20° C., preferentially comprised of methyl acrylate, ethyl acrylate, ethylhexyl acrylate, butyl methylacrylate, and more preferentially butyl acrylate.

More precisely, when A is a methacrylic homo- or copolymer (mostly methacrylic or acrylic with mostly methyl methacrylate), said at least one transparent polymer material comprising the first layer is then advantageously nanostructured polymethyl methacrylate (PMMA) shock.

When A is polystyrene, or an acrylic-styrene or methacrylic-styrene copolymer, said at least one transparent polymer material comprising the first layer belongs to the acrylic block copolymers or of a composition comprising at least one acrylic block copolymer car B is an acrylic or methacrylic homo- or copolymer, but then said at least one transparent polymer material comprising the first layer is not nanostructured polymethyl methacrylate (PMMA) shock.

Initially, i.e. before any laminating operation, the encapsulating assembly is comprised of two layers of encapsulation material, referred to as core layers, between which the set of a plurality of photovoltaic cells is encapsulated. However, after the operation of laminating layers, the layers of encapsulation material melted in order to form only a single layer (or set) wherein the photovoltaic cells are embedded. Before any laminating operation, each layer of encapsulation material can as such have a rigidity defined by a Young's modulus of the encapsulation material greater than or equal to 75 MPa at ambient temperature and a thickness of the layer between 0.2 and 1 mm, even between 0.2 and 0.5 mm.

The assembly encapsulating the plurality of photovoltaic cells is as such comprised by the two core layers, namely the layers of encapsulation material which before laminating are in direct contact with the photovoltaic cells, and therefore do not include the additional layer or layers that can be used to form a rigidity gradient, as described in what follows.

The term “transparent” means that the material of the first layer forming the front face of the photovoltaic module is at least partially transparent to visible light, allowing at least about 80% of this light to pass.

In addition, the expression “plates independent from each other” means that the plates are located at a distance from each other, with each one forming a unitary element independent of the first layer and from each other, superimposed on at least one photovoltaic cell. The bringing together of all of these plates then forms the first layer with a discontinuous aspect.

Furthermore, by the term “encapsulant” or “encapsulated”, it must be understood that the set of a plurality of photovoltaic cells is arranged in a volume, for example hermetically sealed, at least partially formed by the two layers of encapsulation material, connected together after laminating.

Moreover, the expression “ambient temperature” means a temperature between environ 15 and 30° C.

Thanks to the invention, it can as such be possible to provide an alternative solution for the design of a supple and relatively flexible photovoltaic module, that has satisfactory flatness (absence of warping) and also sufficiently robust in order to resist the impacts and mechanical loads undergone, for example after application on a rigid support, even in the absence of the use of glass as the front face of the module which usually provides the flatness and the mechanical resistance of a conventional photovoltaic module, in particular through the use of specific materials for the carrying out of the various layers of the module. In particular, the use of a discontinuous front face can confer to the photovoltaic module according to the invention a flexible nature that makes it possible in particular to facilitate the application thereof on a support that is not flat, for example curved. In addition, the use of an encapsulation material with a high rigidity on either side of the photovoltaic cells can make it possible to suitably protect the photovoltaic cells against the risk of a substantial mechanical load or an impact, by limiting their bending thereof, and therefore limiting the risk of breakage. Furthermore, the absence of the use of a material made of glass for the front face of the photovoltaic module can allow the photovoltaic module according to the invention to have a weight less than that of a photovoltaic module according to prior art, typically of about 12 kg/m², according to the thickness of the various layers used. Finally, the use of a discontinuous front face made of a polymer material can make it possible to prevent thermal expansion problems during the use of the photovoltaic module according to the invention outdoors. Indeed, as the thermal expansion is proportional to the dimensions of the first layer forming the front face of the module, using plates that have dimensions close to those of the photovoltaic cells can make it possible to substantially limit the displacements induced by thermal constraints that can give rise to delaminations or an uncontrolled conformation of the photovoltaic module.

The photovoltaic module according to the invention can further comprise one or several of the following characteristics taken individually or according to any technically permissible combinations.

The photovoltaic module may or may not be applied on a rigid support, for example by gluing. Such a rigid support can be of any type, for example smooth, porous, flat or curved. Such a rigid support can for example be used when the photovoltaic module has to be subjected to high mechanical loads, for example static or dynamic pressures that can range up to 1500 kN/m², even 5000 kN/m².

The first layer forming the front face of the photovoltaic module can be single-layer or multi-layer. In particular, it can comprise a set of transparent layers superimposed between them.

The second layer forming the rear face of the photovoltaic module can also be discontinuous. In other words, the second layer can also comprise a plurality of plates independent from each other, with each plate being located opposite, i.e. superimposed, at least one photovoltaic cell. The presence of a discontinuous rear face on the photovoltaic module according to the invention can for example make it possible to further improve the flexibility of the module, for example in order facilitate the application thereof on a rigid support provided with a surface roughness.

Moreover, although the first layer forming the front face of the photovoltaic module according to the invention, and possibly the second layer forming the rear face of the module, have a discontinuous aspect, the set of a plurality of photovoltaic cells and the encapsulating assembly are advantageously continuous.

According to a particular embodiment of the invention, each plate of the first layer, and possibly of the second layer, can be located opposite several photovoltaic cells. This can in particular be the case for photovoltaic cells of dimensions that are smaller than those of conventional photovoltaic cells, typically 156×156 mm.

In addition, when a single photovoltaic cell is located opposite each plate of the first layer, and possibly of the second layer, each plate can have dimensions at least equal to those of the photovoltaic cell with which it is superimposed.

The photovoltaic module is advantageously devoid of a first layer forming the front face of the module carried out in glass. As such, as indicated hereinabove, it may be possible to improve the lightness and the integration capacity of the photovoltaic module.

As indicated hereinabove, said at least one transparent polymer material comprising the first layer can advantageously be nanostructured polymethyl methacrylate (PMMA) shock, in particular such as the one marketed by the ARKEMA company under the brand ShieldUp®.

The nanostructured PMMA shock can be such as the one described in international application WO 03/062293 A1, international application WO 2006/061523 A1 or international application WO 2012/085487 A1.

Preferentially, the block A is polymethyl methacrylate, phenyl polymethylacrylate, benzyl polymethylacrylate or isobornyl polymethylacrylate, or a copolymer with a base of two or more of methyl methacrylate monomers, phenyl methacrylate, benzyl methacrylate, isobornyl methacrylate. More preferentially, the block A is PMMA modified with acrylic or methacrylic comonomers.

Moreover the block A and/or the block B can comprise styrene comonomers, such as styrene, acrylics or methacrylics, carriers of various chemical functions known to those skilled in the art, for example acid, amide, amine, hydroxy, epoxy or alkoxy functions.

The block B can preferably incorporate comonomers, such as styrene, in order to improve transparency. In addition, the block A can incorporate methacrylic acid in order to increase the thermal resistance thereof.

Advantageously, using nanostructured PMMA shock can make it possible to provide the multi-layer structure that the photovoltaic module forms with a good resistance to mechanical loads and impacts, superior to that of conventional PMMA (i.e. non-shock and non-nanostructured), while still also making it possible to retain a greater transparency than conventional PMMA shock (i.e. non-nanostructured) in the zone of temperatures between 30° C. and 90° C. As such, using nanostructured PMMA shock for the first layer forming the front face of the photovoltaic module can make it possible to take advantage of a very good compromise between mechanical resistance, in particular to impact, transparency, transparency according to the temperature and resistance to ageing. On the contrary, polycarbonate, which has good properties in terms of transparency and resistance to shock, has a very poor resistance to outdoor ageing. Non-shock and non-nanostructured PMMA, which has very good transparency and very good resistance to ageing, resists shock poorly. Likewise, non-nanostructured PMMA shock, which has good resistance to shock and good resistance to ageing, loses its transparency as soon as the temperature increases and is in the neighbourhood of the zone between 30 and 90° C., which forms a normal zone of temperatures for photovoltaic modules.

As indicated hereinabove, the encapsulating assembly is formed, in particular before laminating, by two core layers of encapsulation material located in the immediate vicinity of the set of photovoltaic cells, respectively on either side of the set of photovoltaic cells. This encapsulating assembly can be supplemented, in particular before laminating, with one or several other additional layers of encapsulation material, the rigidity of the additional layer or layers of encapsulation material, other than the two core layers of encapsulation material, decreasing when moving away from the encapsulating assembly.

As such, the module can for example comprise at least one additional layer of encapsulation material, located between the first layer forming the front face of the photovoltaic module and the core layer of encapsulation material in the immediate vicinity.

The two core layers of encapsulation material can have a Young's modulus greater than 100 MPa, and preferably greater than or equal to 200 MPa at ambient temperature. Said at least one additional layer of encapsulation material can have a Young's modulus strictly less than 75 MPa at ambient temperature.

In other words, advantageously, the photovoltaic module is formed from layers of encapsulation material forming a stack of layers wherein a graduation or rigidity gradient is established from the core layers of encapsulation material in contact with the set of photovoltaic cells to the additional layer or layers of encapsulation material that are the farthest away from the core layers.

The additional layer or layers of encapsulation material can be located above and/or below the set of photovoltaic cells, and more preferentially above the set of photovoltaic cells, i.e. between the first layer and the set of photovoltaic cells.

Preferentially, one or several additional layers of encapsulation material, formed by encapsulation materials that are separate from the one or from those that constitute the core layers, are located above the set of photovoltaic cells, in contact with the upper core layer of encapsulation material. Indeed, this can make it possible to limit the thickness of the layers located below the set of photovoltaic cells in order to prevent this zone of the module from sagging, and also to limit the costs of the material of the photovoltaic module.

The additional layer or layers of encapsulation material can be in particular comprised of a material chosen from thermoplastic polyolefins.

Among these thermoplastic polyolefins, it can in particular be possible to use the encapsulants of solar cells of the Dow company, such as the grades of the Enlight® range, or from the DNP company.

The additional layer or layers of encapsulation material can in particular be comprised of functional thermoplastic polyolefins with a polyamide graft base, grafted onto a functional polyolefin backbone with ethylene units, and in particular comprised of thermoplastic polyolefins from the Apolhya® Solar Film range from the Arkema company, having a Young's modulus at ambient temperature between 50 and 100 MPa.

The functional thermoplastic polyolefins from the Apolhya® Solar Film range can be members of the family of graft polymers, also called comb copolymers, wherein macromolecular chains of the functional polyolefin type comprising the main structure or backbone or “body of the comb”, are grafted by side chains or grafts or teeth of the comb, of nonpolyolefinic structure. More particularly, grafted or comb copolymers from the Apolhya® Solar Film range, are comprised of main chains of a functional polyolefin on which are grafted chains made of polyamide or polyester (teeth of the comb or grafts). Yet more particularly, the main chains of a functional polyolefin that can be grafted are majority copolymers with ethylene units comprising functional units, i.e. having other chemical functions that differ from hydrocarbon units. At least one portion of these functional units has a chemical reactivity with regards to terminal functional groups of the grafts (or comb teeth). As such, among the reactive functional units, mention can be made, for example, of the acid, ester or anhydride groups. The reaction of these reactive units with the terminal units of the grafts makes it possible to obtain from the final chemical structure grafted functional polyolefin material. The grafts are comprised of homo- or copolymers chosen from the polyamide and polyester families, having a single reactive terminal end with the reactive functional units of the main chains of functional polyolefin. Preferably, the grafts are comprised of homo- or copolymers of the monoamine terminated polyamide type.

Such materials, in the form of sheets or films, can have both a sufficient rigidity, greater than that of the sheets or films of conventional ethylene vinyl acetate (EVA), as well as better resistance to ageing than the latter.

Moreover, and independently, when one or more additional layers of encapsulation material are used, making it possible to establish a rigidity gradient between the core layers of encapsulation material with high rigidity and the outermost layer or layers in contact with the front face or the rear face of the photovoltaic module, these layers have less rigidity than the rigidity of core layers of encapsulation material. This makes it possible to relax the structure in order to mechanically withstand the differential expansions better, in particular when the front face and/or the rear face of the module have substantial rigidity through their thickness and/or the mechanical module of the materials used. Indeed, in the absence of one or more additional layers of encapsulation material, the photovoltaic module can be relatively rigid, which in light of the differences in the expansion coefficients of the layers can generate during expansions and/or contractions during the manufacture or the use of the photovoltaic module, stresses that can lead to local delaminations, in particular at the interface between the first layer forming the front face and the rest of the layers constituting the module. The encapsulation material forming the two core layers of encapsulation material of the encapsulating assembly can have a Young's modulus at ambient temperature greater than or equal to 100 MPa, in particular greater than or equal to 150 MPa, even 200 MPa. It is in particular 220 MPa.

The encapsulating assembly can be formed from two core layers of encapsulation material that have identical or different thicknesses.

The encapsulating assembly can moreover be comprised of a material of the isomer type, such as the ionomer marketed under the name of Jurasol® ionomer of the DG3 type by the Jura-plant company or the ionomer marketed under the name of PV5414 by the Du Pont company, having a Young's modulus greater than or equal to 200 MPa at ambient temperature.

The second layer forming the rear face of the photovoltaic module can be comprised of at least one polymer material.

Alternatively, the second layer forming the rear face of the photovoltaic module can be comprised of at least one composite material, in particular of the polymer/glass fibre type.

The second layer moreover has, more preferably, a thermal expansion coefficient less than or equal to 20 ppm, and more preferably less than or equal to 10 ppm.

The second layer forming the rear face of the photovoltaic module may or may not be transparent.

The rigidity of the second layer forming the rear face of the photovoltaic module can be defined by a factor of rigidity, corresponding to Young's modulus at ambient temperature of the material of the second layer multiplied by the thickness of the second layer, between 5 and 15 GPa·mm.

In addition, the rigidity of the second layer forming the rear face of the photovoltaic module can be defined by a Young's modulus at ambient temperature of the material of the second layer greater than or equal to 1 GPa, and better greater than or equal to 3 GPa, and even better greater than or equal to 10 GPa, and a thickness of the second layer between 0.2 and 3 mm.

In this way, the second layer forming the rear face of the photovoltaic module can have a high rigidity that can as such limit its flexibility. However, this high rigidity can make it possible to reduce, and even prevent, the punching of the photovoltaic cells by the rear face of the module, i.e. the appearance of cracks and/or of breakage of the photovoltaic cells, when the latter is for example applied on a support that has a substantial surface roughness.

The spacing between two neighbouring, or consecutive or adjacent, photovoltaic cells, can be greater than or equal to 1 mm, in particular between 1 and 30 mm, and preferably greater than or equal to 3 mm, in particular between 10 and 20 mm.

The two neighbouring photovoltaic cells considered can be two neighbouring cells of the same series (designated by the term “string”) or two neighbouring cells belonging respectively to two consecutive series of the set of photovoltaic cells.

The presence of substantial spacing between the photovoltaic cells can make it possible to obtain a spacing as substantial between the plates of the first layer forming the front face of the photovoltaic module. In this way, the discontinuous aspect of the front face of the module is accentuated, as such making it possible to provide the module with flexibility in order to facilitate the possible application thereof on a rigid support.

Advantageously, the spacing between two neighbouring plates of the first layer, and possibly of the second layer, is less than or equal to the spacing between two neighbouring photovoltaic cells.

According to an alternative, the photovoltaic module can comprise a so-called “shock-absorbing” intermediate layer located between the first layer forming the front face of the photovoltaic module and the assembly encapsulating the plurality of photovoltaic cells, allowing for the assembly, in particular by gluing, of the first layer on the encapsulating assembly.

The intermediate layer can be comprised of at least one polymer material, in particular of a thermosetting or thermoplastic polymer resin.

The intermediate layer can have for example the form of a sheet or be of liquid form. It can be adhesive, for example of the PSA type, or not. It can be implemented hot or at ambient temperature.

The rigidity of the intermediate layer can be defined by a Young's modulus of the material of the intermediate layer less than or equal to 50 MPa at ambient temperature and a thickness of the intermediate layer between 0.01 and 1 mm. The intermediate layer can in particular fulfil two main functions. On the one hand, it can allow for the adhesion of the first layer forming the front face of the photovoltaic module on the encapsulating assembly for cases where the two layers are not chemically compatible. On the other hand, it can make it possible to create within the photovoltaic module a “shock-absorbing” layer of a certain flexibility that makes it possible to improve the resistance to impact and to the mechanical loads of the module.

This intermediate layer can be optional, in particular absent when there is a chemical compatibility between the first layer forming the front face of the photovoltaic module and the encapsulating assembly.

The intermediate layer can also play a role in the rigidity gradient provided by the additional layer or layers of encapsulation material. As such, the intermediate layer can have a rigidity that is less than that of the additional layer or layers of encapsulation material.

The photovoltaic module can further comprise an adhesive layer located between the second layer forming the rear face of the photovoltaic module and the assembly encapsulating the plurality of photovoltaic cells that allows for the assembly, in particular by gluing, of the second layer on the encapsulating assembly.

The term “adhesive layer” means a layer that allows, once the photovoltaic module is carried out, the second layer to adhere to the encapsulating assembly. This is therefore a layer that allows for a chemical compatibility and adhesion between the encapsulant and the rear face.

Moreover, the thickness of the first layer forming the front face of the photovoltaic module can be greater than or equal to 0.1 mm, in particular between 0.5 and 6 mm.

Furthermore, the invention further has for object, according to another of its aspects, a photovoltaic module comprising at least:
a transparent first layer forming the front face of the photovoltaic module intended to receive a luminous flux,
a set of a plurality of photovoltaic cells arranged side-by-side and connected together electrically,
an assembly encapsulating the plurality of photovoltaic cells,
a second layer forming the rear face of the photovoltaic module, the encapsulating assembly and the set of a plurality of photovoltaic cells being located between the first and second layers, characterised in that the first layer consists of at least one transparent polymer material and comprises a plurality of plates independent from each other, each plate being located opposite at least one photovoltaic cell, in such a way as to form a discontinuous front face of the photovoltaic module, in that the rigidity of the encapsulating assembly is defined by a Young's modulus at ambient temperature of the encapsulation material greater than or equal to 75 MPa and a thickness of the encapsulating assembly between 0.4 and 1 mm, and in that the encapsulating assembly is formed by two core layers of encapsulation material located in the immediate vicinity of the set of photovoltaic cells, respectively on either side of the set of photovoltaic cells, with this encapsulating assembly being supplemented, in particular before laminating, with one or more other additional layers of encapsulation material, the rigidity of the additional layer or layers of encapsulation material, other than the two core layers of encapsulation material, decreasing when moving away from two core layers of encapsulation material.

In addition, the invention further has for object, according to another of its aspects, a photovoltaic structure assembly, comprising:
a rigid support,
a photovoltaic module such as defined hereinabove, and
a fixing layer, in particular by gluing, located between the rigid support and the photovoltaic module, allowing for the adherence of the photovoltaic module to the rigid support.

The rigid support can have a surface roughness.

The use of the fixing layer can make it possible to obtain a reinforced rear face of the photovoltaic module, making it possible to prevent the risk of punching of the photovoltaic cells by the rear face when the rigid support has a high surface roughness and the photovoltaic module is subjected to an impact or a high mechanical load. Indeed, the interface between the rear face of the module and the rigid support can as such be filled in with a protective binder.

Furthermore, the invention also has for object, according to another of its aspects, the use, for the application thereof on a rigid support of a photovoltaic module comprising at least:
one transparent first layer forming the front face of the photovoltaic module intended to receive a luminous flux,
a set of a plurality of photovoltaic cells arranged side-by-side and connected together electrically,
an assembly encapsulating the plurality of photovoltaic cells,
a second layer forming the rear face of the photovoltaic module, the encapsulating assembly and the set of a plurality of photovoltaic cells being located between the first and second layers, the first layer comprising a plurality of plates independent from each other, each plate being located opposite at least one photovoltaic cell, in such a way as to form a discontinuous front face of the photovoltaic module, the rigidity of the encapsulating assembly being defined by a Young's modulus of the encapsulation material greater than or equal to 75 MPa at ambient temperature and a thickness of the encapsulating assembly between 0.4 and 1 mm, the first layer being in particular comprised of at least one transparent polymer material belonging to the acrylic block copolymers or of a composition comprising at least one acrylic block copolymer having the following general formula:

(A)ₙB

wherein:
n is an integer greater than or equal to 1;
A is an acrylic or methacrylic homo- or copolymer having a glass transition temperature greater than 50° C., in particular greater than 80° C., or polystyrene, or an acrylic-styrene or methacrylic-styrene copolymer; and
B is an acrylic or methacrylic homo- or copolymer having a glass transition temperature less than 20° C., in particular comprised of methyl acrylate, ethyl acrylate, ethylhexyl acrylate, butyl methylacrylate or butyl acrylate, and the photovoltaic module being applied on the rigid support by the intermediary of a fixing layer.

Advantageously, the first layer can be comprised of at least one transparent polymer material being nanostructured polymethyl methacrylate (PMMA) shock, when A is a methacrylic homo- or copolymer (mostly methacrylic or acrylic with mostly methyl methacrylate).

Moreover, the invention further has for object, according to another of its aspects, a method for carrying out a photovoltaic module such as defined hereinabove or a photovoltaic structure assembly such as defined hereinabove, comprising at least the following step a) and successively at least the following step b) or the step c) of:

a) hot laminating at a temperature greater than 150° C. of all of the layers that comprise the photovoltaic module other than the first layer forming the front face of the photovoltaic module and a possible so-called “shock-absorbing” intermediate layer, located between the first layer and the assembly encapsulating the plurality of photovoltaic cells,

b) laminating at a temperature less than or equal to 150° C., better 125° C., for example at ambient temperature, of the first layer forming the front face of the photovoltaic module, and of the possible intermediate layer, on the layers comprising the photovoltaic module laminated together during the first step a),

c) gluing, with beforehand depositing of a liquid glue whether or not reactive, or pressing, in particular hot pressing, of the first layer forming the front face of the photovoltaic module, and of the possible intermediate layer, on the layers comprising the photovoltaic module laminated together during the first step a).

As such, the steps b) and c) comprise two alternative steps carried out after the step a).

The liquid glue is preferentially made solid via evaporation of solvent, by polymerisation and/or cross-linking reaction triggered by temperature, or by electromagnetic radiation. Pressing can be used, as an alternative to gluing, when there is already a chemical compatibility in terms of adhesion between the first layer, or the possible intermediate layer, and the upper layer of the layers laminated together during the first step a).

During the first step a) of laminating, the layers comprising the photovoltaic module concerned are as such the set of a plurality of photovoltaic cells, the encapsulating assembly and the second layer forming the rear face of the photovoltaic module.

The possible “shock-absorbing” intermediate layer can make it possible to facilitate the gluing of the first layer forming the front face of the module on the other layers. This intermediate layer is optional. It can in particular not be necessary when there is a chemical compatibility between the first layer forming the front face of the module and the encapsulating assembly.

Advantageously, the implementing of at least two steps of laminating in the method according to the invention for the carrying out of the photovoltaic module can make it possible to overcome any thermal expansion problems that can occur due to the use of a front face of the module made from a polymer material.

Indeed, certain layers of the photovoltaic module require being laminated at a temperature greater than or equal to 140° C., or even 150° C., but the laminating at this level of temperature in a single step, in accordance with the practice according to prior art, of all of the layers of the module, including the one forming the front face of the module, can give rise to an uncontrolled conformation and to substantial delaminations of the front face of the photovoltaic module due to the excessive mechanical stresses generated.

Also, the presence of at least one second step of laminating at a lower temperature that for the first step, for the laminating of the front face of the photovoltaic module, possibly combined with the presence of a so-called “shock-absorbing” intermediate layer that allows for the gluing of the front face of the module onto the encapsulation material and the absorbing of the thermal stresses, can make it possible to limit, and even prevent, thermal expansion.

Alternatively, the invention also has for object, according to another of its aspects, a method for carrying out a photovoltaic module such as defined hereinabove or a photovoltaic structure assembly such as defined hereinabove, comprising the following single step of:

d) hot laminating at a temperature greater than or equal to 150° C. of all of the layers that comprise the photovoltaic module.

Pour the carrying out of a photovoltaic structure assembly such as defined hereinabove, the steps a) and b), or the steps a) and c), or the step d), can be followed by the step e) of fixing the photovoltaic module onto a rigid support in order to form the photovoltaic structure assembly, by means of a fixing layer of the photovoltaic structure assembly.

As indicated hereinabove, the thickness of the encapsulating assembly can be between 0.4 and 1 mm, with the latter resulting from the association via laminating of at least two layers of encapsulation material with each one having a thickness between 0.2 and 0.5 mm. These two layers of encapsulation material can moreover have different thicknesses.

The photovoltaic module, the photovoltaic structure assembly and the method according to the invention can comprise any one of the aforementioned characteristics, taken individually or according to any technically permissible combinations with other characteristics.

### BRIEF DESCRIPTION OF THE DRAWING

The invention can be understood better when reading the following detailed description of a non-limiting embodiment of the latter, as well as by examining the single FIGURE, diagrammatical and partial, of the annexed drawing, which shows, as a cross-section and as an exploded view, an embodiment of a photovoltaic structure assembly comprising a photovoltaic module in accordance with the invention.

In this single FIGURE, the various portions shown are not shown necessarily to a uniform scale, in order to make the FIGURE more legible.

### DETAILED DESCRIPTION OF A PARTICULAR EMBODIMENT

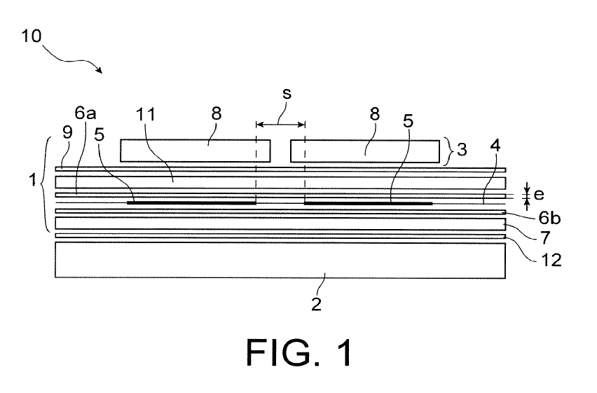

Note that FIG. 1 corresponds to an exploded view of the photovoltaic structure assembly 10 before the steps of laminating of the method according to the invention. Once these steps have been carried out, the various layers are in reality superimposed on one another, but also slightly deformed in such a way that at least the plates 8 of the first layer 3 sink into the assembly formed by the intermediate layer 9 and the encapsulating assembly 6a, 6b which are deformed. The steps of laminating provide a hot pressing and in a vacuum. According to the thicknesses of the various layers, the plates 8 can be flush or not with the photovoltaic module 1, the material of the intermediate layer 9 and perhaps that of the encapsulating assembly 6a, 6b also able to fill in at least one portion of the spaces between the plates 8.

As explained hereinabove, the photovoltaic module 1 in accordance with the invention is designed to be sufficiently flexible in order to be able to apply it, in particular by gluing, onto a possible rigid support 2, able to have a surface roughness, in other words not necessarily flat and smooth. In addition, the photovoltaic module 1 in accordance with the invention is also provided to resist static or dynamic pressures that can range up to 1500 kN/m², even 5000 kN/m². The rigid support 2 is advantageously sufficiently rigid to not become deformed when the same stress as that applied to the photovoltaic module 1 is applied. It can for example be formed by a roof covering, be made of concrete or sheet metal, among others.

As can as such be seen in FIG. 1, the photovoltaic module 1 comprises a transparent first layer 3 forming the front face of the module 1 intended to receive a luminous flux, an encapsulating assembly 6a, 6b, obtained by the melting of two upper 6a and lower 6b core layers of encapsulation material, with this encapsulating assembly being overmounted by an additional layer of encapsulation material 11, located above the upper core layer of encapsulation material 6a, a set 4 of photovoltaic cells 5 taken between the two upper 6a and lower 6b core layers of encapsulation material, and a second layer 7 forming the rear face of the photovoltaic module 1 intended to be glued to the rigid support 2.

The two core layers of encapsulation material 6a and 6b forming the encapsulating assembly, as well as the possible intermediate layer 9 described hereinbelow, form a relatively supple structure that can be carried out from a single material or from several materials in the event of chemical incompatibility.

In accordance with the invention, the first layer 3 is comprised of a transparent polymer material of the nanostructured polymethyl methacrylate (PMMA) shock type. It can in particular be nanostructured PMMA shock marketed by the ARKEMA company under the brand ShieldUp®.

In addition, the first layer 3 comprises a plurality of plates 8 independent from each other, with each plate 8 being located opposite a photovoltaic cell 5, in such a way as to form a discontinuous front face of the photovoltaic module 1. The thickness of the first layer 3 can be greater than 0.1 mm, and ideally between 0.5 and 6 mm. In this example, the first layer 3 is as such comprised of several plates 8, of dimensions equal to 162×162 mm, of nanostructured PMMA shock with a thickness equal to 3 mm.

Moreover, advantageously, the rigidity of the additional layer of encapsulation material 11 is chosen to be lower than the respective rigidities of the two core layers of encapsulation material 6a, 6b. In particular, the two core layers of encapsulation material 6a, 6b can have a Young's modulus E at ambient temperature greater than 75 MPa, advantageously greater than 100 MPa, and more preferably greater than 200 MPa, and the additional layer of encapsulation material 11 can have a Young's modulus E at ambient temperature less than 75 MPa, and more preferably less than or equal to 50 MPa.

In other words, advantageously, the photovoltaic module 1 is comprised of an assembly of layers of encapsulation material 11, 6a, 6b forming a stack of layers wherein a graduation or rigidity gradient is established from the core layers of encapsulation material 6a, 6b in contact with the set 4 of photovoltaic cells 5 to the additional layer of encapsulation material 11.

Although in this example a single additional layer of encapsulation material 11 has been considered, several additional layers of encapsulation material 11 can alternatively be stacked via overlapping on the upper core layer of encapsulation material 6a and/or on the lower core layer of encapsulation material 6b. This stacking it then carried out in such a way that for each new layer n+1 stacked, its Young's modulus E at ambient temperature is less than the Young's modulus E at ambient temperature of the preceding layer n.

The additional layer of encapsulation material 11 can be comprised of a material chosen from thermoplastic polyolefins, and in particular thermoplastic polyolefins from the Apolhya® Solar Film range from the Arkema company, for example such as the Apolhya® Solar Film encapsulant of grade R333A or EXP A having a Young's modulus E between 50 and 100 MPa at ambient temperature and an intermediate rigidity between that of the ionomer of the core layers of encapsulation material 6a, 6b and that of the TPU of the intermediate layer 9.

Moreover, the photovoltaic cells 5 are interconnected electrically with one another with a spacing s between two neighbouring cells 5 between 1 and 30 mm. The photovoltaic cells 5 can be so-called “crystalline” photovoltaic cells, i.e. which have a silicon crystal or silicon polycrystalline base, with a homojunction or heterojunction, and a thickness less than or equal to 250 μm. In addition, in this example, each plate 8 extends by overlapping on either side of the underlying photovoltaic cell 5 over a distance of about 3 mm, in such a way that the spacing between two adjacent plates 8 is here equal to the spacings enter two neighbouring cells 5 less about 2 times 3 mm, i.e. about 6 mm.

Furthermore, the rigidity of each core layer of encapsulation material 6a and 6b is defined by a Young's modulus E at ambient temperature of the encapsulation material greater than or equal to 50 MPa, preferably greater than or equal to 200 MPa, and a thickness e of the layer 6a, 6b between 0.2 and 1 mm.

The core layers of encapsulation material 6a and 6b form an encapsulating assembly preferentially chosen to be an ionomer such as the ionomer marketed under the name of ionomer Jurasol® of the DG3 type by the Jura-plast company or the ionomer marketed under the name of PV5414 by the Du Pont company, having a Young's modulus greater than or equal to 200 MPa at ambient temperature and a thickness of about 500 μm.

The second layer 7 forming the rear face of the photovoltaic module 1 is comprised of a polymer material such as thermosetting resins such as resins with an epoxy base, whether or not transparent, or a composite material, for example of the polymer/glass fibre type.

In addition, as can be seen in FIG. 1, the photovoltaic module 1 also comprises a so-called “shock-absorbing” intermediate layer 9 located between the first layer 3 and the additional layer of encapsulation material 11.

The intermediate layer 9 is optional and substantially has its utility if there is a chemical incompatibility between the first layer 3 and the additional layer of encapsulation material 11.

The intermediate layer 9 allows for the gluing of the first layer 3 onto the additional layer of encapsulation material 11.

The intermediate layer 9 is for example comprised of a standard encapsulant used in the field of photovoltaics, such as ethylene vinyl acetate (EVA) copolymer, a polyolefin, silicone, thermoplastic polyurethane, polyvinyl butyral, among others. It can further be constituted by a liquid resin of the acrylic, silicone or polyurethane type, single-component or bicomponent, heat cross-linkable, photochemically or cold (i.e. at ambient temperature). It can also be comprised of an adhesive that is sensitive to pressure of the PSA (“Pressure-Sensitive Adhesive”) type.

In this example, the intermediate layer 9 is comprised of a thermoplastic film, namely thermoplastic polyurethane also known under the acronym TPU, such as TPU of the TPU Dureflex® A4700 type, marketed by the Bayer company or PX1001 marketed by the American company Polyfilm, with a thickness equal to environ 380 μm.

The intermediate layer 9 makes it possible to fulfil two main functions. On the one hand, it allows for the adhesion of the first layer 3 on the additional layer of encapsulation material 11 for the case where the two layers are not compatible chemically. On the other hand, it makes it possible to create within the photovoltaic module 1 a “shock-absorbing” layer of a certain flexibility that makes it possible to improve the resistance to shocks and to the mechanical loads of the module 1.

Moreover, the photovoltaic structure assembly 10 in accordance with the invention shown in FIG. 1 also comprises a rigid support 2. The rigid support 2 can be of any type of material. It can be flat or curved, smooth or rough.

In order to allow for the gluing of the photovoltaic module 1 onto the rigid support 2, the assembly 10 also comprises a fixing layer 12. This fixing layer 12 is comprised of a glue for adhering the module 1 to the rigid support 2.

A method for carrying out a photovoltaic module 1 and a photovoltaic structure assembly 10 in accordance with the invention shall now be described.

The method comprises a first step of hot laminating a) at a temperature of about 170° C. and in a vacuum (pressure less than or equal to 10 mbar) of the layers comprising 11, 6a, 4, 6b and 7 of the photovoltaic module 1 other than the first layer 3 and the intermediate layer 9. This first step a) of laminating is carried out for about 15 minutes so as to obtain a “laminate” of encapsulated photovoltaic cells 5. The parameters for the laminating, such as the temperature, time and pressure, can however depend on the encapsulating material used.

Then, the method comprises a second step of hot laminating b) at a temperature of about 125° C. and in a vacuum of the “laminate” obtained during the first step a) with the first layer 3 forming the front face of the photovoltaic module 1 using the intermediate layer 9. This second step b) is carried out during a period of about 30 minutes so as to obtain the photovoltaic module 1 according to the invention. Before implementing this second step b), the plates 8 of the first layer 3 can advantageously be treated using a Corona treatment equipment so as to obtain a surface energy that is greater than or equal to 48 dyn/cm.

These first a) and second b) steps of laminating are then followed by a step of fixing the photovoltaic module 1 onto the rigid support 2 which makes it possible to form the photovoltaic structure assembly 10.

Consequently, the photovoltaic module 1 in accordance with the invention can have a mechanical resistance that is increased suitable for constraining applications in terms of mechanical stresses, but also have a flexibility by pieces due to the presence of a discontinuous front face 3, allowing it to have different forms in order to adapt to different types of surfaces, for example uneven or with imperfect flatness. In addition, the presence of a reinforced rear face 7 can make it possible to improve the resistance to the punching of this rear face 7 of the module 1, with this punching able to result from the roughness of the support 2 whereon the module 1 is applied and which can lead to cracks of the photovoltaic cells 5 of the photovoltaic module 1.

Of course, the invention is not limited to the embodiment which has just been described. Various modifications can be made to it by those skilled in the art.

The expression “comprising a” must be understood as being synonymous with “comprising at least one”, unless mentioned otherwise.

1-23. (canceled)

24. A photovoltaic module comprising:
a transparent first layer forming a front face of the photovoltaic module configured to receive a luminous flux;
a set of a plurality of photovoltaic cells arranged side-by-side and connected together electrically;
an assembly encapsulating the plurality of photovoltaic cells;
a second layer forming a rear face of the photovoltaic module, the encapsulating assembly and the set of a plurality of photovoltaic cells being located between the first and second layers;
wherein the first layer comprises a plurality of plates independent from each other, each plate being located opposite at least one photovoltaic cell, to form a discontinuous front face of the photovoltaic module;
wherein rigidity of the encapsulating assembly is defined by a Young's modulus of the encapsulation material greater than or equal to 75 MPa at ambient temperature and a thickness of the encapsulating assembly of between 0.4 and 1 mm; and
wherein the first layer includes at least one transparent polymer material belonging to acrylic block copolymers or of a composition comprising at least one acrylic block copolymer having following formula:
(A)ₙB
wherein:
n is an integer greater than or equal to 1;
A is an acrylic or methacrylic homo- or copolymer having a glass transition temperature greater than 50° C., or polystyrene, or an acrylic-styrene or methacrylic-styrene copolymer; and
B is an acrylic or methacrylic homo- or copolymer having a glass transition temperature less than 20° C., comprised of methyl acrylate, ethyl acrylate, ethylhexyl acrylate, butyl methylacrylate or butyl acrylate.

25. A module according to claim 24, wherein the block A is chosen from polymethyl methacrylate, phenyl polymethylacrylate, benzyl polymethylacrylate or isobornyl polymethylacrylate, or a copolymer with a base of two or more of methyl methacrylate monomers, phenyl methacrylate, benzyl methacrylate, or isobornyl methacrylate.

26. A module according to claim 25, wherein the block A is of the polymethyl methacrylate modified with acrylic or methacrylic comonomers.

27. A module according to claim 24, wherein the block A and/or the block B comprise styrene, acrylic, or methacrylic comonomers.

28. A module as claimed in claim 24, wherein the block B incorporates comonomers, and wherein the block A incorporates methacrylic acid.

29. A module as claimed in claim 24, wherein the encapsulating assembly includes two core layers of encapsulation material located in an immediate vicinity of the set of photovoltaic cells, respectively on either side of the set of photovoltaic cells.

30. A module as claimed in claim 24, wherein the encapsulation material of the layers forming the encapsulating assembly has a Young's modulus at ambient temperature greater than or equal to 100 MPa.

31. A module as claimed in claim 24, wherein the encapsulating assembly is supplemented with one or more other additional layers of encapsulation material, rigidity of the additional layer or layers of encapsulation material decreasing when moving away from the encapsulating assembly.

32. A module according to claim 29, further comprising at least one additional layer of encapsulation material, located between the first layer and the core layer of encapsulation material in the immediate vicinity.

33. A module according to claim 32, wherein the at least one additional layer of encapsulation material has a Young's modulus at ambient temperature less than 75 MPa.

34. A module according of claim 31, wherein the additional layer or layers of encapsulation material are comprised of a material chosen from thermoplastic polyolefins.

35. A module according to claim 34, wherein the additional layer or layers of encapsulation material are comprised of functional thermoplastic polyolefins with a polyamide graft base, grafted onto a functional polyolefin backbone with ethylene units.

36. A module as claimed in claim 24, wherein the second layer forming the rear face of the photovoltaic module is comprised of at least one polymer material and/or of at least one composite material.

37. A module as claimed in claim 24, wherein rigidity of the second layer forming the rear face of the photovoltaic module is defined by a factor of rigidity, corresponding to the Young's modulus at ambient temperature of the material of the second layer multiplied by the thickness of the second layer, between 5 and 15 GPa·mm.

38. A module as claimed in claim 24, wherein spacing between two neighbouring photovoltaic cells is greater than or equal to 1 mm.

39. A module as claimed in claim 24, further comprising a shock-absorbing intermediate layer located between the first layer forming the front face of the photovoltaic module and the assembly encapsulating the plurality of photovoltaic cells, allowing for assembly of the first layer on the encapsulating assembly.

40. A module according to claim 34, wherein the intermediate layer is comprised of at least one polymer material.

41. A module according to claim 39, wherein rigidity of the intermediate layer is defined by a Young's modulus at ambient temperature of the material of the intermediate layer less than or equal to 50 MPa and a thickness of the intermediate layer between 0.01 and 1 mm.

42. A photovoltaic structure assembly, comprising:
a rigid support;
a photovoltaic module as claimed in claim 24; and
a fixing layer located between the rigid support and the photovoltaic module, allowing for adherence of the photovoltaic module to the rigid support.

43. Use, for application thereof on a rigid support of a photovoltaic module comprising:
one transparent first layer forming a front face of the photovoltaic module configured to receive a luminous flux;
a set of a plurality of photovoltaic cells arranged side-by-side and connected together electrically;
an assembly encapsulating the plurality of photovoltaic cells;
a second layer forming a rear face of the photovoltaic module, the encapsulating assembly and the set of a plurality of photovoltaic cells being located between the first and second layers;
the first layer comprising a plurality of plates independent from each other, each plate being located opposite at least one photovoltaic cell, to form a discontinuous front face of the photovoltaic module;
rigidity of the encapsulating assembly being defined by a Young's modulus of the encapsulation material greater than or equal to 75 MPa at ambient temperature and a thickness of the encapsulating assembly of between 0.4 and 1 mm;
the first layer being comprised of at least one transparent polymer material belonging to the acrylic block copolymers or of a composition comprising at least one acrylic block copolymer having following formula:
(A)ₙB
wherein:
n is an integer greater than or equal to 1;
A is an acrylic or methacrylic homo- or copolymer having a glass transition temperature greater than 50° C., or polystyrene, or an acrylic-styrene or methacrylic-styrene copolymer; and
B is an acrylic or methacrylic homo- or copolymer having a glass transition temperature less than 20° C., and
the photovoltaic module being applied on the rigid support by an intermediary of a fixing layer.

44. A method for carrying out a photovoltaic module according to claim 24, comprising:
a) hot laminating at a temperature greater than 150° C. the set of layers that comprise the photovoltaic module other than the first layer forming the front face of the photovoltaic module and any shock-absorbing intermediate layer, located between the first layer and the encapsulating assembly the plurality of photovoltaic cells;
b) laminating at a temperature less than or equal to 150° C., the first layer forming the front face of the photovoltaic module, and any intermediate layer, on the layers that comprise the photovoltaic module laminated together during a),
c) gluing, with beforehand depositing of a liquid glue whether or not reactive, or pressing, the first layer forming the front face of the photovoltaic module, and any intermediate layer, on the that comprise the photovoltaic module laminated together during a).

45. A method for carrying out a photovoltaic module according to claim 44, further comprising:
d) hot laminating at a temperature greater than or equal to 150° C. all of the layers that comprise the photovoltaic module.

46. A method for carrying out a photovoltaic structure assembly according to claim 44, and successively further comprising:
d) fixing the photovoltaic module onto a rigid support to form the photovoltaic structure assembly, by a fixing layer of the photovoltaic structure assembly.
